(19) United States
(12) Patent Application Publication
(10) Pub. No.: US 2024/0408687 A1
(43) Pub. Date: Dec. 12, 2024

(54) SOLDER SOLDERING METHOD USING LASER

(71) Applicant: S.S.P. Inc., Incheon (KR)

(72) Inventor: Heui Jong JU, Incheon (KR)

(73) Assignee: S.S.P. Inc., Incheon (KR)

(21) Appl. No.: 18/618,734

(22) Filed: Mar. 27, 2024

(30) Foreign Application Priority Data
Jun. 9, 2023 (KR) 10-2023-0074352

(51) Int. Cl. B23K 1/005; B23K 1/00; B23K 1/20; B23K 101/40; H01L 23/00

(52) U.S. Cl. CPC B23K 1/0056; B23K 1/0016; B23K 1/20; B23K 2101/40; H01L 24/81; H01L 24/83; H01L 2224/81224; H01L 2224/83224

(57) ABSTRACT

Proposed is a solder soldering method using a laser. The solder soldering method performs solder soldering within a few seconds by using the laser so that warpage occurring due to a difference in a coefficient of thermal expansion between a chip and a substrate may be reduced, thermal shock that occurs on the chip and the substrate may be reduced, an entire process time may be reduced, and defects due to an uneven solder processing temperature may be reduced. The solder soldering method includes a supplying process in which a substrate having solder is supplied to a substrate fixing member, a preheating process in which the substrate and the solder are preheated, an attachment process in which the substrate is irradiated with the laser and the solder is melted and attached to the substrate, and a discharging process in which the substrate is moved to a tray.

### CROSS REFERENCE TO RELATED APPLICATION

The present application claims priority to Korean Patent Application No. 10-2023-0074352, filed Jun. 9, 2023, the entire contents of which are incorporated herein for all purposes by this reference.

### BACKGROUND OF THE INVENTION

### Field of the Invention

The present disclosure relates to a solder soldering method using a laser. More particularly, the present disclosure relates to a solder soldering method using a laser, the solder soldering method performing solder soldering within a few seconds by using the laser so that warpage that occurs due to a difference in a coefficient of thermal expansion between a chip and a substrate is capable of being reduced, thermal shock that occurs on the chip (a component and so on) and the substrate is capable of being reduced, an entire process time is capable of being reduced, and an uneven solder processing temperature is capable of being reduced.

### Description of the Related Art

In an existing semiconductor manufacturing process or an existing PCB manufacturing process, in order to perform an electrical connection between a substrate and solder (a solder ball, a bump, a copper pillar, a solder paste, and so on), the substrate is attached to the solder by using a Mass Reflow (MR) that is a classical hot air method in which a high temperature heat source is applied inside a structure such as an oven and by using an IR lamp and so on as a heat source.

In a simplified description, it can be said that the existing processes are performed such that the solder is melted and solidified by exposing all the chip and the substrate to the high temperature for a long time.

However, such methods take a long time, and since heat is applied to the chip (the component and so on) and to the entire substrate, there is a high possibility that a thermal deformation phenomenon and a package warpage phenomenon will occur.

The package warpage is a phenomenon caused by a difference in the Coefficient of Thermal Expansion (CTE) between the chip and the substrate, which causes many problems in a process that is performed at a later stage.

### Document of Related Art

(Patent Document 1) Korean Patent Application Publication No. 10-2022-0083629 (published on Jun. 20, 2022)

### SUMMARY OF THE INVENTION

Accordingly, the present disclosure has been made keeping in mind the above problems occurring in the related art, and an objective of the present disclosure is to provide a solder soldering method using a laser, the solder soldering method performing solder soldering within a few seconds by using the laser so that warpage that occurs due to a difference in a coefficient of thermal expansion between a chip and a substrate is capable of being reduced, and thermal shock that occurs on the chip (a component and so on) and the substrate is capable of being reduced.

In addition, another objective of the present disclosure is to provide a solder soldering method using a laser, the solder soldering method being performed such that the laser irradiation is performed after upper and lower portions of a substrate are simultaneously preheated while the substrate and solder that are supplied to a base are moved to a laser irradiation portion, thereby being capable of reducing an entire process time and also being capable of preventing defects due to an uneven solder processing temperature.

In order to solve these problems, in the present disclosure, there is provided a solder soldering method using a laser, the solder soldering method including: a supplying process in which a substrate having solder positioned on an upper portion of the substrate is supplied to an upper portion of a substrate fixing member that constitutes a soldering apparatus; a preheating process in which the substrate and the solder are preheated while the substrate is moved together with the substrate fixing member; an attachment process in which the upper portion of the substrate is irradiated with the laser so that the solder is melted and attached to the upper portion of the substrate; and a discharging process in which the substrate having the solder attached to the substrate is moved to a tray.

Here, in the preheating process, a lower portion of the substrate may be heated to a set temperature by a lower heater provided in the soldering apparatus, and the upper portion of the substrate and the solder may be heated to a set temperature by an upper heater provided in an upper portion of the soldering apparatus.

At this time, an adsorption portion for adsorbing a lower surface of the substrate may be formed in the substrate fixing member, an inner portion of the adsorption portion may maintain a set vacuum level, and gas contained inside the adsorption portion may be heated to a temperature equal to or more than a set temperature.

In addition, in the attachment process, a first mask configured to prevent the laser irradiating an edge of the substrate may be used, the first mask may include a blocking portion configured to block the laser irradiation, and the first mask may include a heat dissipation portion which is in contact with the upper surface of the substrate and which is configured to discharge excessive heat.

Here, in the attachment process, a second mask for protecting a chip mounted on the substrate from the laser may be further provided between the substrate and a laser irradiation portion, the second mask may include a transparent plate formed of a transparent material through which the laser is capable of being transmitted, and the second mask may include a masking portion which is formed on a first side of the transparent plate so as to correspond to a position of the chip mounted on the substrate and which is configured to block the laser.

According to the present disclosure described above, since solder soldering is performed within a few seconds by using the laser, warpage that occurs due to a difference in a coefficient of thermal expansion between the chip and the substrate is capable of being reduced, and thermal shock that occurs on the chip (the component and so on) and the substrate is capable of being reduced.

In addition, in the present disclosure, since the laser irradiation is performed after the upper and lower portions of the substrate are simultaneously preheated while the substrate and the solder that are supplied to the base are moved to the laser irradiation portion, the entire process time is capable of being reduced, and also defects due to an uneven solder processing temperature are capable of being prevented.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a flowchart illustrating a solder soldering method using a laser according to the present disclosure;

FIG. 2 is a conceptual view illustrating a preheating process of the solder soldering method using the laser according to the present disclosure;

FIG. 3 is a conceptual view illustrating an attachment process of the solder soldering method using the laser according to the present disclosure;

FIG. 4 is a conceptual view illustrating the use of a second mask in the attachment process of the solder soldering method using the laser according to the present disclosure; and

FIG. 5 is a conceptual view illustrating a state in which a masking portion of the second mask blocks a laser irradiating a chip of a substrate during the attachment process of the solder soldering method using the laser according to the present disclosure.

### DETAILED DESCRIPTION OF THE INVENTION

Hereinafter, an exemplary embodiment of the present disclosure will be described in detail with reference to the accompanying drawings. The same constituent elements in the drawings are denoted by the same reference numerals, and a repeated description of the same elements will be omitted. In addition, it should be understood that the present disclosure may be implemented in many different forms and is not limited to the described embodiments.

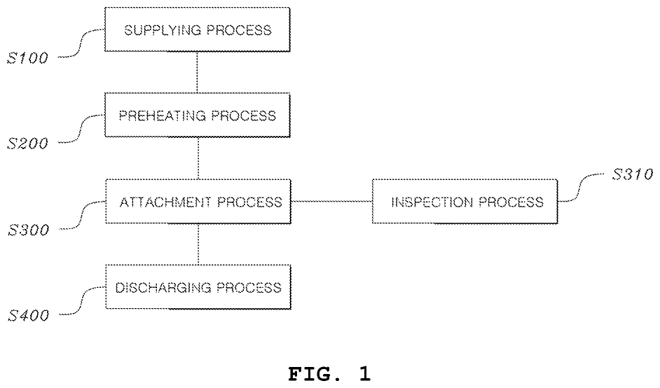

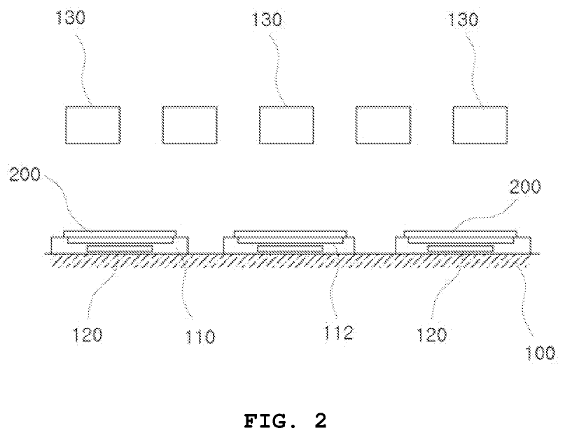

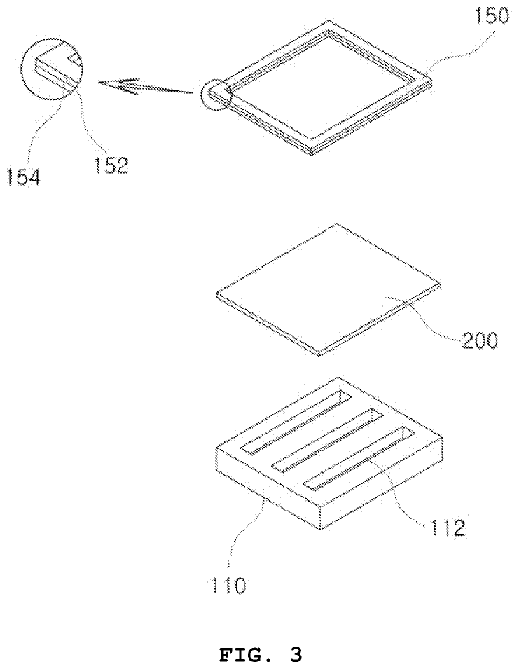

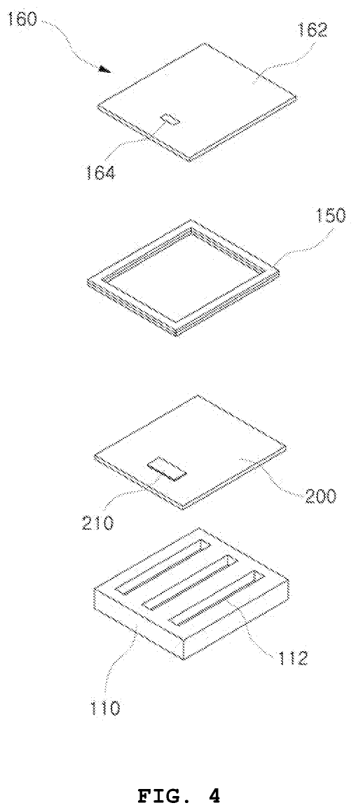

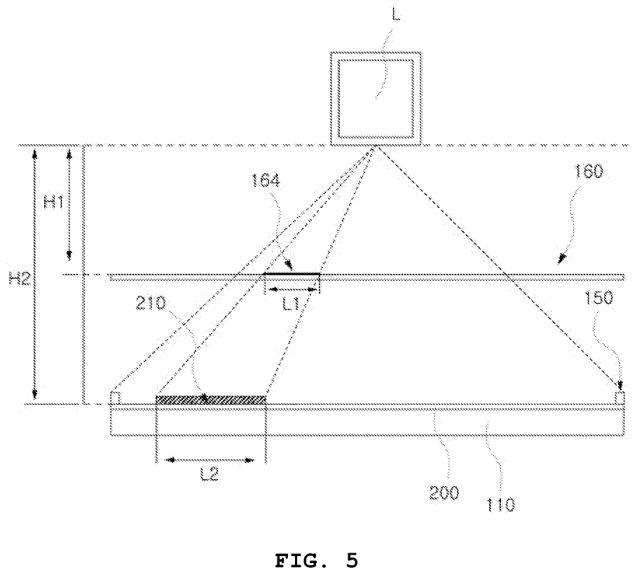

FIG. 1 is a flowchart illustrating a solder soldering method using a laser according to the present disclosure, FIG. 2 is a conceptual view illustrating a preheating process of the solder soldering method using the laser according to the present disclosure, FIG. 3 is a conceptual view illustrating an attachment process of the solder soldering method using the laser according to the present disclosure, FIG. 4 is a conceptual view illustrating the use of a second mask in the attachment process of the solder soldering method using the laser according to the present disclosure, and FIG. 5 is a conceptual view illustrating a state in which a masking portion of the second mask blocks a laser irradiating a chip of a substrate during the attachment process of the solder soldering method using the laser according to the present disclosure.

The present disclosure relates to a solder soldering method using a laser. As illustrated in FIG. 1 to FIG. 4, the solder soldering method includes a supplying process S100 in which a substrate 200 having solder (not illustrated) positioned on an upper portion thereof is supplied to an upper portion of a substrate fixing member 110 that constitutes a soldering apparatus, a preheating process S200 in which the substrate 200 and the solder are preheated while the substrate 200 is moved together with the substrate fixing member 110, an attachment process S300 in which the upper portion of the substrate 200 is irradiated with the laser so that the solder is melted and attached to the upper portion of the substrate 200, and a discharging process S400 in which the substrate 200 having the solder attached thereto is moved to a tray.

Here, in the solder soldering apparatus used in the present disclosure, the substrate fixing member 110 is provided on an upper portion of a base 100, and is moved by a separate moving apparatus (not illustrated) such that each process is capable of being performed.

Therefore, in the present disclosure, since the upper portion of the substrate 200 is irradiated with the laser, the solder is capable of being rapidly heated equal to or more than a melting point of the solder and the solder is capable of being rapidly attached to the upper portion of the substrate 200, so that the time required for the entire process may be reduced.

In addition, in the supplying process S100, the substrate 200 is discharged from a substrate storage apparatus (not illustrated) such as a magazine, a cassette, and so on that are provided separately, and the substrate 200 is supplied to the upper portion of the substrate fixing member 110.

At this time, when the substrate 200 is seated on the upper portion of the substrate fixing member 110, a processing area on the substrate 200 and an irradiation position of a laser beam are matched by using a Pattern Recognition System (PRS) or a mechanical alignment method, so that the solder may be stably attached to the upper portion of the substrate 200 in the attachment process S300.

Meanwhile, after the supplying process S100 is completed, the substrate 200 is moved to a position where the attachment process S300 is performed while the solder is in a state in which the solder is seated on the upper portion of the substrate 200, and the preheating process S200 in which the substrate 200 and the solder are preheated to a set temperature is performed during the moving process.

Here, in the preheating process S200, a lower portion of the substrate 200 is heated to the set temperature by a lower heater 120 provided in the soldering apparatus, and the upper portion of the substrate 200 and the solder are heated to the set temperature by an upper heater 130 provided in an upper portion of the soldering apparatus.

At this time, the lower heater 120 is configured to heat the lower portion of the substrate 200 which is mounted inside the substrate fixing member 110 and which is fixed to the upper portion of the substrate fixing member 110 to 70 degrees Celsius to 90 degrees Celsius, and the upper heater 130 is configured to heat the substrate 200 moving the upper portion of the base 100 and the upper portion of the solder to 95 degrees Celsius to 105 degrees Celsius.

In addition, an adsorption portion 112 for adsorbing a lower surface of the substrate 200 is formed in the substrate fixing member 110, and an inner portion of the adsorption portion 112 maintains a set vacuum level, thereby solidly fixing the substrate 200 positioned on an upper portion of the adsorption portion 112.

Here, the adsorption portion 112 is formed in a hole shape or a groove shape, and is configured to adsorb the lower portion of the substrate 200 seated on the upper portion of the adsorption portion 112. The substrate fixing member 110 is formed of a material having a predetermined elastic force, and the substrate 200 is pressed by a set pressure in the supplying process S100, so that air inside the adsorption portion 112 is discharged to the outside, thereby forming the set vacuum level.

At this time, the lower heater 120 is provided inside the substrate fixing member 110 as described above, and is configured to heat gas contained inside the adsorption portion 112 to the set temperature.

Therefore, the upper heater 130 and the lower heater 120 heat the upper and lower portions of the substrate 200 and the solder as well as the gas contained inside the adsorption portion 112 to the set temperature, so that heat transfer (loss) to the lower portion of the substrate 200 may be prevented when the laser irradiation is performed and the substrate 200 and the solder are heated in the attachment process S300 to be described later.

That is, when the temperature of the lower portion of the substrate 200 is low or the temperature of the gas contained inside the adsorption portion 112 is low, heat loss occurs while the laser irradiation is performed during the attachment process S300 due to a phenomenon in which heat is transferred to the lower portion of the substrate 200 through an I/O circuit pad in the substrate 200. Furthermore, a difference in the amount of heat transfer to the lower portion occurs since a metal density of a connection portion is different for each I/O circuit pad, so that the temperature of the entire solder is not maintained uniformly and defects occur.

Therefore, as described above, in the present disclosure, the substrate 200, the solder, and also the gas contained in the adsorption portion 112 are preheated through the preheating process S200, so that heat loss may be prevented in the attachment process S300 and the temperature of the entire solder may be maintained uniformly, thereby preventing defects.

In addition, when the substrate fixing member 110 is formed of a hard material, although not illustrated in the drawings, a through-hole in communication with the outside is formed in the adsorption portion 112 that is formed in the hole shape or the groove shape, and an adsorption apparatus (not illustrated) provided at the outside is connected to the through-hole and is configured to maintain the inside of the adsorption portion 112 at the set vacuum level.

Meanwhile, in the attachment process S300, the solder is melted by the laser irradiating the upper portion of the substrate 200 fixed to the upper portion of the substrate fixing member 110. In the attachment process S300, as illustrated in FIG. 3, a first mask 150 configured to prevent the laser irradiating an edge of the substrate 200 is used, so that the edge of the substrate 200 is capable of being prevented from being damaged by heat.

Here, the first mask 150 is formed in a frame shape and is configured such that the laser irradiating the edge of the substrate 200 is blocked but the laser irradiating the center portion of the substrate 200 is allowed, thereby allowing the solder to be rapidly melted so that the solder is attached to an upper portion of the substrate 200.

At this time, the first mask 150 includes a blocking portion 152 which is positioned on an upper portion of the first mask 150 and which is configured to block the laser irradiation, and includes a heat dissipation portion 154 which is in contact with the upper surface of the substrate 200 and which is configured to discharge excessive heat. The blocking portion 152 is formed of a material having a low thermal conductivity, and the heat dissipation portion 154 is formed of a metal or a ceramic type material having a good thermal conductivity.

Therefore, since the laser irradiating the edge of the substrate 200 is blocked and also heat conducted from the center portion of the substrate 200 is discharged from the heat dissipation portion 154 to the outside, so that a situation in which heat is gathered to the edge of the substrate 200 and a polymer constituting the substrate 200 is damaged by heat may be prevented.

In addition, as described above, the process of the present disclosure may be performed while a chip 210 and so on are not separately mounted on the upper surface of the substrate 200. However, as illustrated in FIG. 4, in the attachment process S300, a second mask 160 for protecting the chip 210 mounted on the substrate 200 from the laser may be further provided between the substrate 200 and a laser irradiation portion (not illustrated).

Here, the second mask 160 includes a transparent plate 162 formed of a transparent material (Quartz, Znse, Borosilca, Fused Sillica, and so on) through which the laser is capable of being transmitted, and includes a masking portion 164 which is formed on a first side of the transparent plate 162 so as to correspond to a position of the chip 210 mounted on the substrate 200 and which is specially and optically treated so as to block the laser.

At this time, in the attachment process S300, a lifting apparatus (not illustrated) provided on a first side of the base 100 is controlled so that the first mask 150 is in contact with the edge of the substrate 200 and the second mask 160 is moved to a set height, and then the laser irradiates the upper surface of the substrate 200.

Therefore, by the first mask 150 and the masking portion 164 of the second mask 160, the laser does not irradiate the edge of the substrate 200 and does not irradiate the chip 210, so that defects may be prevented from occurring.

At this time, a length L1 of the masking portion 164 of the second mask 160, a height H1 of the second mask 160 from a laser head L, a length L2 of the chip 210 of the substrate 200, and a height H2 of the substrate 200 from the laser head L satisfy the equation L1:L2=H1:H2, so that an area of the laser blocked by the masking portion 164 of the second mask 160 may match an area of the chip 210.

After the solder is stably attached to the upper surface of the substrate 200 through the attachment process S300, the discharging process S400 is performed. In the discharging process S400, the substrate 200 to which the solder is attached is discharged to the separately provided tray (not illustrated) by a separate discharging apparatus (not illustrated).

Meanwhile, in the attachment process S300, an inspection process S310 for determining whether the substrate 200 to which the solder is attached is defective may further be performed. In the inspection process S310, the temperature of the upper surface of the substrate 200 is detected through a temperature sensor (not illustrated) provided on a side portion of the laser irradiation portion, thereby determining whether the substrate 200 is defective.

Here, an infrared sensor, a thermal infrared camera, and so on that are capable of measuring temperature in a non-contact manner may be used as the temperature sensor. Conventionally, the melting point of lead-free solder is 217 degrees Celsius. In this situation, the temperature of the substrate 200 is determined to be 240 degrees Celsius to 350 degrees Celsius as an appropriate temperature.

Therefore, when the temperature detected by the temperature sensor during the attachment process S300 is within the set temperature range, the substrate 200 is determined as a good product. When the temperature is outside the set temperature range, the substrate 200 is determined as a defective product.

Of course, a normal temperature range may vary according to a solder material.

Although the exemplary embodiment of the present disclosure has been described above, the scope of the present disclosure is not limited thereto. The scope of the rights of the present disclosure extends to those that are substantially equivalent to the embodiments of the present disclosure, and various modifications may be made by those skilled in the art to which the present disclosure pertains without departing from the spirit of the present disclosure.

### INDUSTRIAL APPLICABILITY

The present disclosure relates to a solder soldering method using a laser. More particularly, the present disclosure relates to a solder soldering method using a laser, the solder soldering method performing solder soldering within a few seconds by using the laser so that warpage that occurs due to a difference in a coefficient of thermal expansion between a chip and a substrate is capable of being reduced, thermal shock that occurs on the chip (a component and so on) and the substrate is prevented, an entire process time is reduced, and defects due to an uneven solder processing temperature are prevented.

What is claimed is:

1. A solder soldering method using a laser, the solder soldering method comprising:
a supplying process in which a substrate having solder positioned on an upper portion of the substrate is supplied to an upper portion of a substrate fixing member that constitutes a soldering apparatus;
a preheating process in which the substrate and the solder are preheated while the substrate is moved together with the substrate fixing member;
an attachment process in which the upper portion of the substrate is irradiated with the laser so that the solder is melted and attached to the upper portion of the substrate; and
a discharging process in which the substrate having the solder attached to the substrate is moved to a tray.

2. The solder soldering method of claim 1, wherein, in the preheating process, a lower portion of the substrate is heated to a set temperature by a lower heater provided in the soldering apparatus, and the upper portion of the substrate and the solder are heated to a set temperature by an upper heater provided in an upper portion of the soldering apparatus.

3. The solder soldering method of claim 1, wherein an adsorption portion for adsorbing a lower surface of the substrate is formed in the substrate fixing member, an inner portion of the adsorption portion maintains a set vacuum level, and gas contained inside the adsorption portion is heated to a temperature equal to or more than a set temperature.

4. The solder soldering method of claim 1, wherein, in the attachment process, a first mask configured to prevent the laser irradiating an edge of the substrate is used, the first mask includes a blocking portion configured to block the laser irradiation, and the first mask includes a heat dissipation portion which is in contact with the upper surface of the substrate and which is configured to discharge excessive heat.

5. The solder soldering method of claim 4, wherein, in the attachment process, a second mask for protecting a chip mounted on the substrate from the laser is further provided between the substrate and a laser irradiation portion, and
the second mask includes a transparent plate formed of a transparent material through which the laser is capable of being transmitted, and includes a masking portion which is formed on a first side of the transparent plate so as to correspond to a position of the chip mounted on the substrate and which is configured to block the laser.
